(19) United States
(12) Patent Application Publication
(10) Pub. No.: US 2010/0270874 A1
(43) Pub. Date: Oct. 28, 2010

(54) ARRANGEMENT FOR A POWER ELECTRONICS UNIT IN A HYBRID VEHICLE

(75) Inventors: Hans Stervik, Kärma (SE); Ivar Alm, Ockero (SE)

Correspondence Address: WRB-IP LLP, 801 N. Pitt Street, Suite 123, ALEXANDRIA, VA, 22314, US

(73) Assignee: Volvo Lastvagnar AB, Götenborg (SE)

(21) Appl. No.: 12/747,904

(22) PCT Filed: Feb. 26, 2008
(86) PCT No.: PCT/SE08/00160

§ 371 Date: Jun. 12, 2010

Related U.S. Application Data
(63) Continuation-in-part of application No. PCT/SE2007/001149, filed on Dec. 20, 2007.

(51) Int. Cl. H02K 9/22; H02K 9/19; B60R 13/08; H05K 7/20; B60K 6/48

(52) U.S. Cl. 310/51; 310/52; 310/54; 361/707; 180/65.25; 903/902; 180/65.21

(57) ABSTRACT

In an arrangement for a power electronics unit in a HEV, the HEV including a combustion engine, an electric motor/generator, a transmission, the power electronics unit is shaped as a plate. The plate is extended along a transmission side, the power electronics unit is fixed to the power train with a first attachment point. All attachment points have a total thermal conductivity corresponding to more than 10 degrees temperature difference on a Kelvin-scale between the power electronics unit and outside surface of said first transmission side and/or outside surface of the motor/generator for 5 kW of heat originating from one side of said attachment point. Embodiments also including sound damping capabilities are disclosed. The arrangement facilitates use of fewer parts and increased functionality.

### BACKGROUND AND SUMMARY

The present invention relates to an arrangement in a hybrid electric vehicle (HEV) equipped with a combustion engine, a transmission and at least one electric motor/generator, and where a power electronics unit of the electric motor/generator is mounted on a gearbox of said transmission.

The need to reduce fossil fuel consumption and emissions in vehicles powered by an internal combustion engine (ICE) is well known. Vehicles powered by electric motors attempt to address these needs. However, electric vehicles have limited range and limited power capabilities and need substantial time to recharge their batteries. An alternative solution is to combine both an ICE and electric traction motor into one vehicle. Such vehicles are typically called Hybrid Electric Vehicles (HEVs). See for example, U.S. Pat. No. 5,343,970.

The HEV is described in a variety of configurations. Many HEV patents disclose systems in which an operator is required to select between electric and internal combustion operation. In other configurations, the electric motor drives one set of wheels and the ICE drives a different set.

Other, more useful, configurations have developed. For example, a Series Hybrid Electric Vehicle (SHEV) configuration is a vehicle with an engine (most typically an ICE) connected to an electric motor called a generator. The generator, in turn, provides electricity to a battery and another motor, called a traction motor. In the SHEV, the traction motor is the sole source of wheel torque. There is no mechanical connection between the engine and the drive wheels.

A Parallel Hybrid Electrical Vehicle (PHEV) configuration has an engine (most typically an ICE) and an electric motor that together provide the necessary wheel torque to drive the vehicle. Additionally, in the PHEV configuration, the motor can be used as a generator to charge the battery from the power produced by the ICE. The PHEV has usually a transmission between the ICE and -drive wheels of the vehicle in order to be able to alter gear ratio between the ICE and the drive wheels and also in many cases between the electric motor and the drive wheels.

A Parallel/Series Hybrid Electric Vehicle (PSHEV) has characteristics of both PHEV and SHEV configurations and is typically known as a “powersplit” configuration. In the PSHEV, the ICE is mechanically coupled to two electric motors in a planetary gearset transaxle. A first electric motor, the generator, is connected to a sun gear. The ICE is connected to a carrier. A second electric motor, a traction motor, is connected to a ring gear (output) via additional gearing in a transaxle. Engine torque powers the generator to charge the battery. The generator can also contribute to the necessary wheel (output shaft) torque. The traction motor is used to contribute wheel torque and to recover braking energy to charge the battery if a regenerative braking system is used.

The desirability of combining an ICE with an electric motor is clear. The ICE IS fuel consumption and emissions are reduced with no appreciable loss of vehicle performance or range. Nevertheless, there remains a substantial opportunity to develop ways to optimize HEV operation.

One area of development is maintaining the desired operating temperature of the HEV components. A cooling system maintains optimal component operation and performance. Overheated components adversely affect efficiency and may eventually cause component failure.

A typical prior art cooling system for an ICE vehicle has a coolant fluid in an enclosed loop that passes through certain vehicle components and a heat exchanger (radiator). A heater core is also typically added to vent engine heat into the passenger compartment as desired. The engine and transmission components typically require cooling from a liquid cooling system. As the coolant circulates through these components in the closed loop, it absorbs heat that is released as the coolant passes through the radiator and heater core.

Coolant flow in the prior art cooling system is typically controlled by a pump driven front-end accessory drive (FEAD). As engine speed increases, the speed of the pump also increases allowing more coolant flow through the system. Additionally, a thermostat within the loop only allows coolant flow through the radiator after the coolant temperature reaches a level at which the engine temperature has stabilized and is considered “warmed up.”

Though simple and reliable, the prior art coolant control system comprising a pump and a thermostat is inadequate for HEVs. For example, the HEV has additional components that require cooling, such as a power electronics unit. Further, the prior art coolant pump does not function when the engine is off. Thus, the typical vehicle accessories driven by the FEAD (including the coolant pump, air conditioning, and power steering) in a conventional vehicle must be powered by an alternate source in the HEV to maintain their functionality when the engine is not running.

The cooling system of a prior art transmission usually comprises a predetermined amount of cooling oil contained in the transmission housing. Some of the gear wheels of the transmission are arranged to be in contact with the cooling oil. When the gear wheels of the transmission rotate during operation, the cooling oil is splashed around in the transmission housing, making the oil coming into contact with basically all parts inside the transmission housing. The oil evens the heat build up in the transmission and contributes to heat being conducted to the transmission housing. The transmission housing can be cooled by ambient air. There are also transmission cooling systems where the oil is circulated by a pump through cooling channels inside the transmission housing and outside the transmission housing to a heat exchanger.

In a heavy HEV, such as a truck more than 5 tonnes it is common for an electric motor/generator to have a performance capacity of more than 100 kW. A power electronics unit for such a relatively powerful electric motor/generator produces a lot of heat during operation that has to be cooled in order to secure the endurance of the electronic components in the power electronics unit. Depending on the specification of the electronic components the maximum allowable temperature varies. Electronic components with less heat resistance are cheap and can have a maximum operative temperature of, for example, 60 degrees Celsius. If the electronic components are specified to withstand temperatures of several hundred degrees Celsius then usually no cooling of the power electronics unit is needed. On the other hand such electronic components are expensive. In the future the power electronics unit is expected to shrink in size due to technical development. The demand for cooling will probably increase since the electronic components will be more densely packed and the electric power handled by the power electronics unit will increase concurrently with the use of more powerful electric motor/generators used in future HEV.

US2004/0134695 discloses a vehicle power train with a combustion engine, a gearbox and an Integrated Starter/Generator (ISG) arranged between the combustion engine and the gearbox. Thus, this document does not disclose a HEV, still, in one embodiment disclosed the power electronics unit of the ISG is arranged on the gearbox. The power demand of an ISG is usually between 1 to 5 kW. The power electronics unit of the ISG is, thus, relatively small and handles a relatively low power. The need for cooling is relatively small. Further, this document discloses an embodiment where a cooling system of the engine also is used for cooling the power electronics unit, when the power electronics unit is arranged on the engine. Only two standard mounting points for a conventional ring gear starter are used when the power electronics unit is mounted on the engine. There is also disclosed a plug in connection between the power electronics unit and the ISG.

Noise from a vehicle power train is always an issue. The transmission components of a vehicle transmission contributes to the increase of noise when in operation. A step geared transmission, especially when gear changing frequently, can cause slamming and rattling, which can be disturbing for the environment. A known noise damping solution is to arrange a relatively thin plate on the outside of the transmission housing. The fixing point of the plate extends around the whole periphery of one side of the plate. Said transmission outside, said plate side and said fixing point enclose a compartment comprising a medium, such as air, with high noise damping capabilities. The fixing point as such can be of a noise damping material such as rubber or the like.

It is desirable to make an arrangement for a power electronics unit in a HEV more space effective with a minimal amount of components. It is also desirable to contribute to a simple and effective installation of a cooling arrangement of said power electronics unit and to contribute to noise reduction of said vehicle.

The arrangement according to an aspect of the invention is an arrangement for a power electronics unit in a hybrid vehicle power train. Said hybrid vehicle power train comprising a combustion engine arranged for propulsion, and an electric motor/generator arranged for propulsion, a transmission with a transmission housing, said transmission is arranged to adapt gear ratio between at least one of said propulsion units and driven vehicle wheels, said motor/generator is arranged to exchange electric power with a power electronics unit, a cooling arrangement comprising cooling channels for cooling at least said power electronics unit, said power electronics unit is shaped substantially as a plate, where a first biggest cross-sectional area of said plate is extended substantially along and substantially within a first transmission side of said transmission housing and covering at least a part of said first transmission side, said power electronics unit is fixed to said hybrid vehicle power train with at least one first attachment point. An aspect of the invention is characterized in that all attachment points have a total thermal conductivity corresponding to more than 10 degrees temperature difference on a Kelvin-scale between said power electronics unit and outside surface of said first transmission side and/or outside surface of said motor/generator for 5 kW of heat originating from one side of said attachment point.

The advantage with the arrangement according to an aspect of the invention is increased space efficiency of the power electronics unit installation at the same time as the thermal conductance of the attachment point/s has/have been decreased, which increases the performance of the cooling arrangement of the power electronics unit.

According to one embodiment of the arrangement according to an aspect of the invention said electric motor/generator and said power electronics unit are connected and fixed to each other to form a first unit, and where said connection is said first attachment point formed by a plug in connection. This embodiment decreases the number of components.

According to one embodiment of the arrangement according to an aspect of the invention said power electronics unit is also attached to said first transmission side via at least a second attachment point made of a material with low thermal conductivity. The advantage is that the carrying performance of the power electronics unit is increased still with low total thermal conductance at the attachment points.

According to one embodiment of the arrangement according to an aspect of the invention, said plug in connection is arranged to transmit at least one of or both of a cooling media for said cooling arrangement and electric power between said motor/generator and said power electronics unit. This decreases the number of components.

According to one embodiment of the arrangement according to an aspect of the invention, said power electronics unit plate is arranged to cover said first transmission side in such a way as to damp noise originating from said transmission.

According to one embodiment of the arrangement according to an aspect of the invention, said second attachment point is extended around the periphery of a side of said power electronics unit facing the transmission, and where said first transmission side, said power electronics unit side and said second attachment point enclose a compartment comprising a medium with low thermal conductivity and high noise damping capabilities. This decreases the number of components at the same time as the functionalities of the installation increases.

According to one embodiment of the arrangement according to an aspect of the invention, said first and second attachment points are of materials with high noise damping capabilities.

According to one embodiment of the arrangement according to an aspect of the invention, said power electronics unit plate comprises said power electronics unit with noise damping material and in an extended part only of a noise damping material, said extended part being arranged in order to better cover said first transmission side. The extended part increases especially the noise reduction capabilities of the installation.

According to one embodiment of the arrangement according to an aspect of the invention, a second electric motor/generator with a second power electronics unit are arranged in connection to said transmission and which together form a second unit via a second plug in connection, and where said second power electronics unit is arranged along a second transmission side of said transmission housing. The advantage is that the number of components can be decreased even further and the noise reduction capabilities can be kept on a high level without any additional noise reducing components.

According to one embodiment of the arrangement according to an aspect of the invention a hose for transmitting cooling media is connected to said power electronics unit on substantially an opposite side of where said plug in connection is arranged. This embodiment is characterized in that said second attachment point is formed of a part of said hose and a cooling hose holder for holding said hose, and where said hose holder is attached to said transmission housing. The advantage is that performance of carrying the power electronics unit can be increased without increase of the number of components and still with low total thermal conductivity at the attachment points.

According to one embodiment of the arrangement according to an aspect of the invention said power electronics unit is only fixed to said first transmission side with at least one of said first attachment point. Said first attachment point can be of a screw-nut type, with a relatively small cross-sectional area. This embodiment can also be combined with a hose for transmitting cooling medium that is connected to said power electronics unit on substantially an opposite side of where said screw-nut type attachment point is arranged, and where said hose and a cooling hose holder for holding said hose forms a further attachment point, and where said hose holder is attached to said transmission housing.

In a further embodiment of said invention a second attachment point can be combined with said screw-nut type attachment point, and where said second attachment point is extended around the periphery of a side of said power electronics unit facing the transmission, and where said first transmission side, said power electronics unit side and said second attachment point enclose a compartment comprising a medium with low thermal conductivity and high noise damping capabilities. This embodiment can also be combined with a hose for transmitting cooling medium that is connected to said power electronics unit on substantially an opposite side of where said screw-nut type attachment point is arranged, and where said hose and a cooling hose holder for holding said hose forms a further attachment point, and where said hose holder is attached to said transmission housing.

### BRIEF DESCRIPTION OF THE DRAWING

The present invention will be described in greater detail below with reference to the accompanying drawings which, for the purpose of exemplification, shows further preferred embodiments of the invention and also the technical background, and in which:

FIGS. 1a and 1b diagrammatically shows a PHEV power train in two different views of an embodiment of the invention.

FIGS. 2a and 2b diagrammatically shows a PHEV power train in two different views of an embodiment of the invention. FIGS. 8a and 8b diagrammatically shows a PHEV power train in two different views of an embodiment of the invention.

FIGS. 3 to 7 and 10 diagrammatically show a top view of further five different PHEV power trains and embodiments of the invention.

FIG. 9 diagrammatically shows a side view of another PHEV power train and embodiments of the invention.

### DETAILED DESCRIPTION

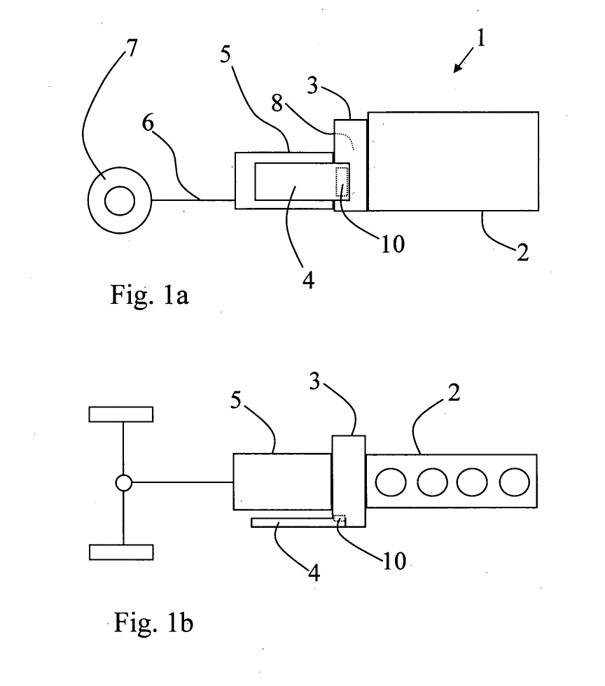

FIGS. 1a and 1b show a PHEV power train 1 comprising a first embodiment of an aspect of the invention. The HEV power train comprises a combustion engine 2, an electric motor/generator 3 with a power electronics unit 4, a transmission 5, a propeller shaft 6 and drive wheels 7.

Arranged mainly coaxially inside of said electric motor/generator 3 is a clutch 8 (not disclosed), which is arranged to transmit torque between the engine 2 and the transmission 5 and which can be engaged or disengaged depending of vehicle condition. The transmission can be a step geared transmission with several gear ratios.

According to an aspect of the invention the power electronics unit 4 is formed as a relatively thick space efficient plate arranged along one side of the transmission 5. The outer of the transmission housing can have a cubic form or a cylinder form or something in between. When the power electronics unit is said to be arranged along a side of said transmission housing, this side is defined as the projection of the outer contour of the transmission housing. Thus, said projection can be a cross sectional plane of the transmission housing along which said power electronics unit is arranged. In the in FIGS. 1a and 1b showed embodiment only one attachment point is used for fixing the power electronics unit to the side of the transmission. This attachment point is formed by a plug in connection 10 arranged to fix the power electronics unit to the electric motor/generator 3. The plug in connection is arranged to have a thermal conductivity corresponding to more than 10 degrees temperature difference on a Kelvin-scale between said power electronics unit and outside surface of said motor/generator for 5 kW of heat originating from one side of said attachment point.

Where thermal conductivity=Q/ΔT=(k·A)/L, and where
Q=heat flow rate,
ΔT=temperature difference,
k=thermal conductivity,
A=area,
L=distance
The SI-unit for thermal conductivity is W-K⁻¹.

Thus, the plug in connection is designed in such a way as to have a relatively low thermal conductivity. This can be achieved for example by choosing materials for the plug in connection having low thermal conductivity. Examples of materials with low thermal conductivity are ceramics, plastics or rubber.

Further, the power electronics unit comprises electronics that has to be cooled in order to secure functionality. A cooling arrangement (not showed) in the power electronics unit is connected to a second cooling arrangement (not showed) of said electric motor/generator via the plug in connection 10, thus integrating the power electronics unit and the electric motor/generator to form a unit. The plug in connection can also comprise electric connections between the power electronics unit 4 and the electric motor/generator 3 or only one of said electric connections and said cooling arrangement connection. Said cooling arrangements form together with other, not shown components, a cooling system of the power electronics unit and the motor/generator.

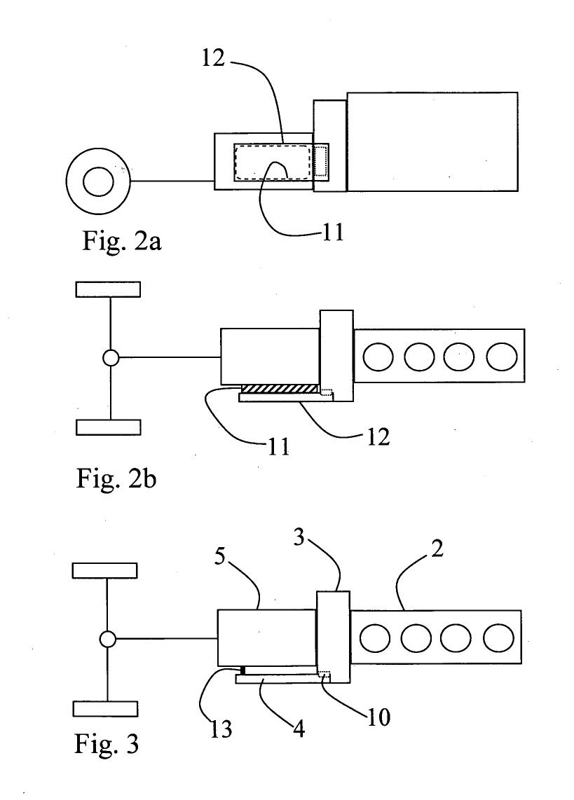

FIGS. 2a and 2b disclose a similar HEV power train as in FIGS. 1a and 1b. In the embodiment of FIGS. 2a and 2b a second attachment point, besides the plug in connection, has been added and is arranged to connect the transmission housing and the power electronics unit. Besides low thermal conductivity this second attachment point together with the power electronics unit plate 12 is designed to damp noise originating from said transmission. This is achieved by the second attachment point extending around the periphery of the side of the power electronics unit facing the side of the transmission (see dashed line in FIG. 2a). Thus, the transmission side, the side of the power electronics unit and the second attachment point are enclosing a compartment comprising a medium with low thermal conductivity and high noise damping capabilities. This medium can for example be air. The second attachment point as such can be made of for example rubber. According to one embodiment of an aspect of the invention this second attachment point is not design for fixing the power electronics unit to the transmission, thus the second attachment point has a very low carrying functionality. The main carrying functionality of the power electronics unit lies in this embodiment on the plug in connection. In a further embodiment this second attachment point as disclosed in FIGS. 2a and 2b can have a carrying functionality. In such an embodiment the second attachment point is made stiffer, for example with stiffer material or a composite, comprising metal parts and parts made of a material with low thermal conductivity and high noise reduction. In order to allow carrying performance to the second attachment point, said attachment point can be fixed to the transmission side and to the power electronics unit in a known manner, with for example different screw/nut solutions, vulcanization etc.

FIG. 3 discloses a similar PHEV power train as in FIGS. 1a and 1b. The only difference is that another variant of a second attachment point 13 has been added that has a power electronics unit carrying functionality with low thermal conductivity. This variant of the second attachment point 13 can for example comprise of a bushing made of a material with low thermal conductivity. The transmission housing and the power electronics unit can each of them be equipped with corresponding flanges (not shown) to which the bushing can be attached by vulcanization and/or screw/nut arrangement (not shown). In one embodiment there can be more than one of this variant of the second attachment point 13. Preferably such an attachment point is arranged substantially on the opposite side of the plug in connection side of the power electronics unit in order to better balance the carrying performance between the plug in connection 10 and this variant of the second attachment point 13. This second attachment point can also be made of a composite (for example metal and a material with low thermal conductivity) with a thermal conductivity corresponding to more than 10 degrees temperature difference on a Kelvin-scale between said power electronics unit and outside surface of said transmission for 5 kW of heat originating from one side of said second attachment point.

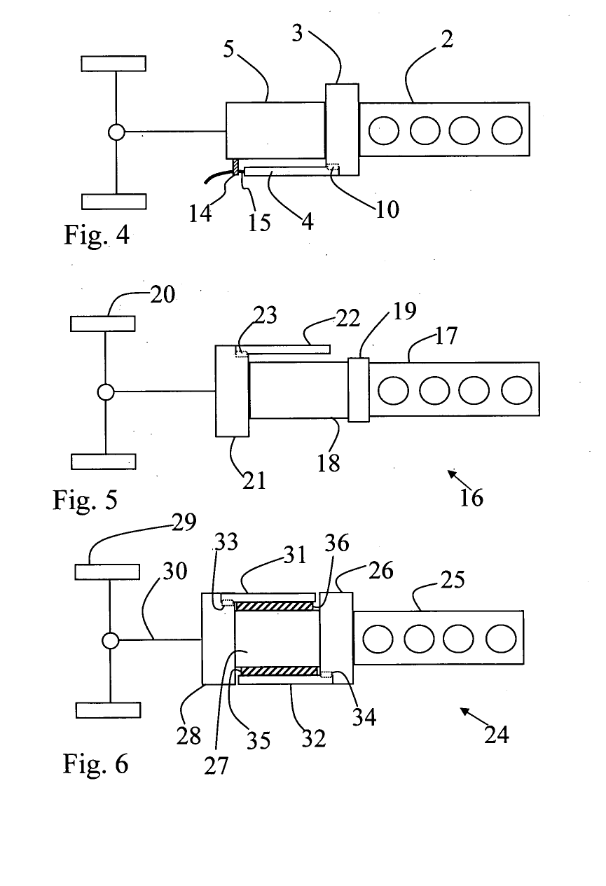

FIG. 4 discloses a similar PHEV power train as in FIG. 3, i.e. FIG. 4 discloses a third variant of a second attachment point that has power electronics unit carrying functionality and low thermal conductivity. This third variant of a second attachment point comprises basically of a part of a hose 15 and a hose holder 14. Said hose can be a cooling hose for transmitting cooling media from a pump and a cooler to the power electronics unit cooling arrangement. The hose holder is fixed to the transmission housing and holding the hose in a fixed position. Thus, this hose holder and hose configuration if made sufficiently strong and stiff can have power electronics unit carrying functionality. Further, at least one of the hose holder or the hose is made of a material with low thermal conductivity. In a further embodiment of an aspect of the invention there can be more than one hose with a hose holder attached to the side of the power electronics unit and attached to the transmission housing. Thus, there can be more than one of this third variant of a second attachment point. As can be seen in FIG. 4 the hose 15 is connected to said power electronics unit 4 on substantially an opposite side of where said plug in connection 10 is arranged. This will better balance the carrying performance between the plug in connection 10 and this third variant of the second attachment point formed of hose 15 and hose holder 14.

FIG. 5 discloses a PHEV power train 16, where a combustion engine 17 is connected to an input shaft (not shown) of a stage geared transmission 18 via a clutch 19. The transmission 18 is further connected to driven wheels 20 via an electric motor/generator 21 attached at an output shaft (not shown) of the transmission 18. The electric motor/generator 21 with its power electronics unit 22 is attached to one end of the transmission housing. Said power electronics unit is attached to the electronic motor/generator via a plug in connection 23 with the same features according to an aspect of the invention as mentioned in the preceding embodiments. In further embodiments of the embodiment shown in FIG. 5 the features of a second attachment point can be used in a similar way as in the embodiments shown in FIGS. 2a, 2b, 3 and 4.

FIG. 6 discloses an embodiment of an aspect of the invention based on a combination of the embodiments mentioned in relation to FIGS. 2a, 2b and 5. Thus, this power train 24 comprises besides a combustion engine 25, a clutch (not shown) coaxially arranged inside of a first electric motor/generator 26, a step geared transmission 27, a second electric motor/generator 28 connected to an output shaft (not shown) of the transmission and driven wheels 29 connected to the second electric motor/generator 28 via for example a propeller shaft 30. The to electric motor/generators have each of them a power electronics unit 31 and 32 arranged in the corresponding way as in the embodiments of FIGS. 5, 2a and 2b, i.e. with plug in connections 33 and 34. Further, both plug in connections 33 and 34 have a second attachment point 35 and 36 corresponding to the second attachment point explained above in connection to the embodiment disclosed by the FIGS. 2a and 2b, i.e. with noise reduction functionality and low heat conductivity. The power electronics units 31 and 32 are arranged on each side of the transmission 27.

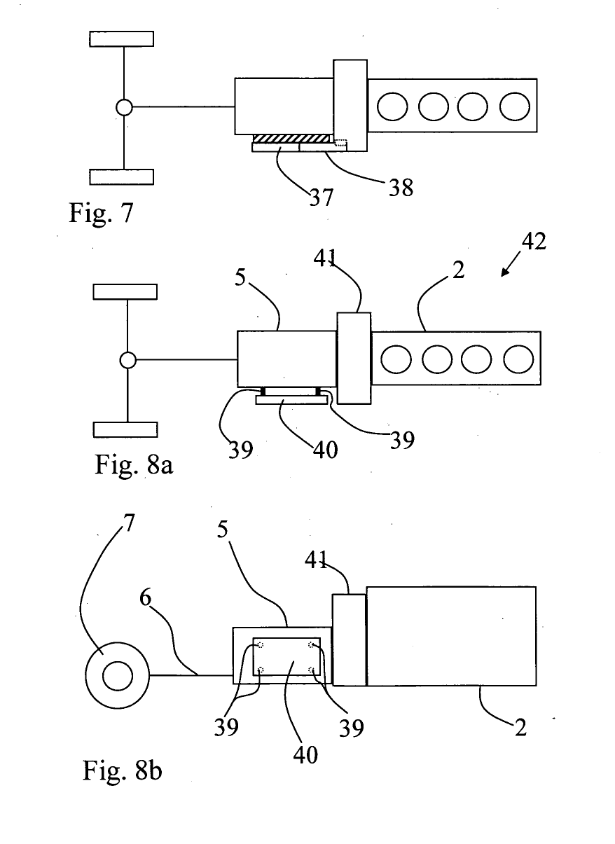

FIG. 7 discloses a similar HEV power train as in FIGS. 2a and 2b. Here said power electronics unit plate comprises said power electronics unit 38 with noise damping material and in an extended part 37 only of a noise damping material. The extended part 37 is fixed to the power electronics unit 38 and arranged in order to better cover said first transmission side in order to increase noise reduction. This embodiment can also be applied to the embodiment shown in FIG. 6.

FIGS. 8a and 8b disclose a HEV power train 42 similar to the one in FIG. 3. According to an aspect of the invention also a power electronics unit 40, as in the above described embodiments, is formed as a relatively thick space efficient plate arranged along one side of the transmission 5. The main difference is that the embodiment of FIGS. 8a and 8b does not have any plug in connection. Thus the motor/generator 41 is slightly modified compared to the one shown in FIG. 3. Instead of a power electronics unit being connected to the electric/motor via said plug in connection (as in FIG. 3), the power electronics unit 40 of the embodiment in FIGS. 8a and 8b is somewhat shorter and is, for example, near the corners of the power electronics unit attached to the transmission housing of the transmission 5. In the shown example the attachment points 39 have a relatively small cross-sectional area, compared to the power electronics unit, and can be embodied for example by a screw-nut arrangement made of a material having a low thermal conductivity corresponding to a thermal conductivity of more than 10 degrees temperature difference on a Kelvin-scale between said power electronics unit and outside surface of said transmission for 5 kW of heat originating from one side of said attachment points 39. In the shown example there is four attachment points 39. The number of attachment points 39 can be more or less than four. The transmission of cooling medium and/or electric power to and from the power electronics unit 40 can be performed in a known manner through hoses and electric wires.

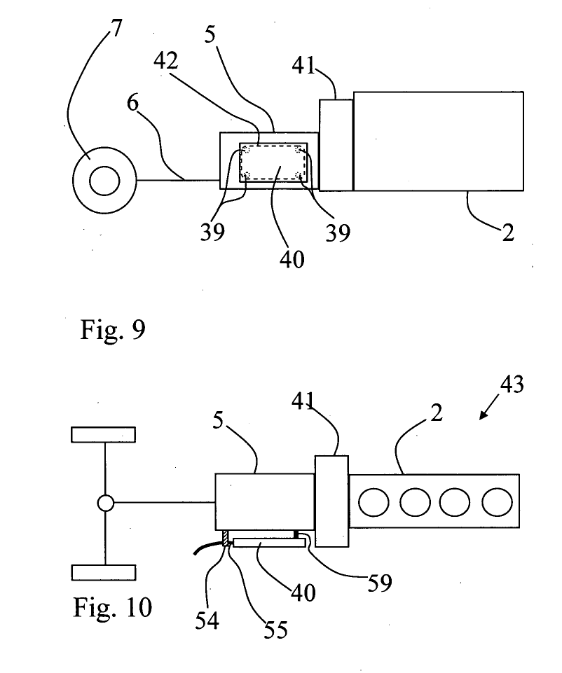

FIG. 9 discloses a similar HEV power train as in FIGS. 8a and 8b. In the embodiment of FIG. 9 a second attachment point 42, besides said above described “screw-nut” attachment points 39, has been added and is arranged to connect the transmission housing and the power electronics unit 40. Besides low thermal conductivity this second attachment point 42 together with the power electronics unit plate 40 is designed to damp noise originating from said transmission 5. Said second attachment point 42 is similar to the second attachment point 11 shown in the embodiment of, for example, FIGS. 2a and 2b. Thus, in this embodiment the carrying functionality and low thermal conductivity of attachment points 39 are combined with the noise reduction capabilities and low thermal conductivity of the second attachment point 42.

FIG. 10 discloses a similar HEV power train 43 as in FIGS. 8a and 8b. FIG. 10 discloses a variant of an attachment point that has power electronics unit carrying functionality and low thermal conductivity and which is similar to the third attachment point 14 and 15 shown in the embodiment of FIG. 4. Thus, this variant of an attachment point, as described above, comprises of a part of a hose 55 and a hose holder 54, both with low thermal conductivity. The hose holder 54 and hose 55 are preferably arranged on the opposite side of the power electronics unit 40 compared to attachment point 59. Thus, a decrease in the number of the attachment points 59 is possible.

In a further not shown embodiment of a HEV power train the attachment points 54, 55 and 59 of the embodiment shown in FIG. 10 can be combined with the noise damping attachment point 42 of the embodiment shown in FIG. 9.

The above mentioned inventive features can also be applied to a heavy PSHEV (power split) with several mechanical fixed gear steps in the transmission.

The invention should not be deemed to be limited to the embodiments described above, but rather a number of further variants and modifications are conceivable within the scope of the following patent claims.

1. Arrangement for a power electronics unit in a hybrid vehicle power train, the hybrid vehicle power train comprising a combustion engine arranged for propulsion, and an electric motor/generator arranged for propulsion, a transmission with a transmission housing, the transmission is arranged to adapt gear ratio between at least one of the propulsion units and driven vehicle wheels, the motor/generator is arranged to exchange electric power with a power electronics unit, a cooling arrangement comprising cooling channels for cooling at least the power electronics unit, the power electronics unit is shaped substantially as a plate, where a first biggest cross-sectional area of the plate is extended substantially along and substantially within a first transmission side of the transmission housing and covering at least a part of the first transmission side, the power electronics unit is fixed to the hybrid vehicle power train with at least one first attachment point, wherein all attachment points have a total thermal conductivity corresponding to more than 10 degrees temperature difference on a Kelvin-scale between the power electronics unit and outside surface of the first transmission side and/or outside surface of the motor/generator for 5 kW of heat originating from one side of the attachment point.

2. Arrangement as in claim 1, wherein the electric motor/generator and the power electronics unit are connected and fixed to each other to form a first unit and where the connection is the first attachment point formed by a plug in connection.

3. Arrangement as in claim 2, wherein the power electronics unit is also attached to the first transmission side via at least a second attachment point made of a material with low thermal conductivity.

4. Arrangement as in claim 2, wherein the plug in connection is arranged to transmit at least one of or both of a cooling medium for the cooling arrangement and electric power between the motor/generator and the power electronics unit.

5. Arrangement as in claim 2, wherein the power electronics unit plate is arranged to cover the first transmission side in such a way as to damp noise originating from the transmission.

6. Arrangement as in claim 3, wherein the second attachment point is extended around the periphery of a side of the power electronics unit facing the transmission, and where the first transmission side, the power electronics unit side and the second attachment point enclose a compartment comprising a medium with low thermal conductivity and high noise damping capabilities.

7. Arrangement as in claim 6, wherein the first and second attachment points are of a material with high noise damping capabilities.

8. Arrangement as in claim 6, wherein the power electronics unit plate comprises the power electronics unit with noise damping material and in an extended part only of a noise damping material, the extended part being arranged in order to better cover the first transmission side.

9. Arrangement as in claim 2, wherein a second electric motor/generator with a second power electronics unit are arranged in connection to the transmission and which together form a second unit via a second plug in connection, and where the second power electronics unit is arranged along a second transmission side of the transmission housing.

10. Arrangement as in claim 3, where a hose for transmitting cooling medium is connected to the power electronics unit on substantially an opposite side of where the plug in connection is arranged, wherein the second attachment point is formed of a part of the hose and a cooling hose holder for holding the hose, and where the hose holder is attached to the transmission housing.

11. Arrangement as in claim 1, wherein the power electronics unit is only fixed to the first transmission side with at least one of the first attachment point.

12. Arrangement as in claim 11, wherein the first attachment point is of a screw-nut type, with a relatively small cross-sectional area.

13. Arrangement as in claim 11, wherein a second attachment point is extended around the periphery of a side of the power electronics unit facing the transmission, and where the first transmission side, the power electronics unit side and the second attachment point enclose a compartment comprising a medium with low thermal conductivity and high noise damping capabilities.

14. Arrangement as in claim 11, where a hose for transmitting cooling medium is connected to the power electronics unit on substantially an opposite side of where the first attachment point is arranged, wherein a third attachment point is formed of a part of the hose and a cooling hose holder for holding the hose, and where the hose holder is attached to the transmission housing.

15. Arrangement as in claim 1, wherein the hybrid vehicle power train is a parallel hybrid electric vehicle power train.
